(19) United States
(12) Patent Application Publication
(10) Pub. No.: US 2025/0199082 A1
(43) Pub. Date: Jun. 19, 2025

(54) BATTERY IMPEDANCE TESTING METHOD, CHIP AND BATTERY IMPEDANCE TESTING SYSTEM USING THE SAME

(71) Applicant: Nanjing Silergy Micro Technology Co., Ltd., Nanjing (CN)

(72) Inventors: Sihua Wen, Nanjing (CN); Zhongjie Sun, Nanjing (CN); Zhao Lu, Nanjing (CN)

(21) Appl. No.: 18/972,197

(22) Filed: Dec. 6, 2024

(30) Foreign Application Priority Data
Dec. 18, 2023 (CN) 202311747061.X

(51) Int. Cl. G01R 31/389; G01R 31/36; G01R 31/3828; G01R 31/3835

(52) U.S. Cl. CPC G01R 31/389; G01R 31/3648; G01R 31/3828; G01R 31/3835

(57) ABSTRACT

A chip for testing an impedance of a battery module, can include: at least one current excitation port configured to control an excitation current applied to the battery module; at least one voltage sampling port configured to sample a response voltage generated on the battery module; a control module configured to perform Fourier transform on the excitation current and the response voltage to generate impedance information of the battery module; and where the excitation current is configured as a superposition signal of at least two square wave current signals with different frequencies.

### RELATED APPLICATIONS

This application claims the benefit of Chinese Patent Application No. 202311747061.X, filed on Dec. 18, 2023, which is incorporated herein by reference in its entirety.

### FIELD OF THE INVENTION

The present invention generally relates to the field of power electronics, and more particularly to battery impedance testing methods and systems.

### BACKGROUND

As one of the necessary parts of electric vehicles, lithium battery performance affects the overall performance of the electric vehicle. Using modern testing methods to study the performance of lithium-ion batteries is an important way to reduce battery costs, improve cruising range, and prevent battery accidents. By detecting the impedance of the battery, the performance parameters of the automobile battery can be well understood.

### BRIEF DESCRIPTION OF THE DRAWINGS

FIG. 1 is a schematic circuit diagram of a first example battery impedance testing system, in accordance with embodiments of the present invention.

FIG. 2 is a schematic circuit diagram of a first example chip, in accordance with embodiments of the present invention.

FIG. 3 is a waveform diagram of an example excitation current, in accordance with embodiments of the present invention.

FIG. 4 is a schematic diagram of an example amplitude spectrum of the impedance, in accordance with embodiments of the present invention.

FIG. 5 is a schematic diagram of an example phase spectrum of the impedance, in accordance with embodiments of the present invention.

FIG. 6 is a schematic circuit diagram of a second example battery impedance testing system, in accordance with embodiments of the present invention.

FIG. 7 is a schematic circuit diagram of a second example chip, in accordance with embodiments of the present invention.

### DETAILED DESCRIPTION

Reference may now be made in detail to particular embodiments of the invention, examples of which are illustrated in the accompanying drawings. While the invention may be described in conjunction with the preferred embodiments, it may be understood that they are not intended to limit the invention to these embodiments. On the contrary, the invention is intended to cover alternatives, modifications and equivalents that may be included within the spirit and scope of the invention as defined by the appended claims. Furthermore, in the following detailed description of the present invention, numerous specific details are set forth in order to provide a thorough understanding of the present invention. However, it may be readily apparent to one skilled in the art that the present invention may be practiced without these specific details. In other instances, well-known methods, procedures, processes, components, structures, and circuits have not been described in detail so as not to unnecessarily obscure aspects of the present invention.

A commonly used battery impedance testing method is the battery impedance spectrum (EIS) testing method, which is widely used in the research of anode and cathode materials analysis of lithium-ion batteries, lithium-ion deintercalation kinetic parameters research, solid electrolyte, interface reaction, and SOC prediction. In current battery impedance testing methods, an excitation current with a single frequency can excite the battery, such that the impedance value of only one effective frequency point can be obtained in one test.

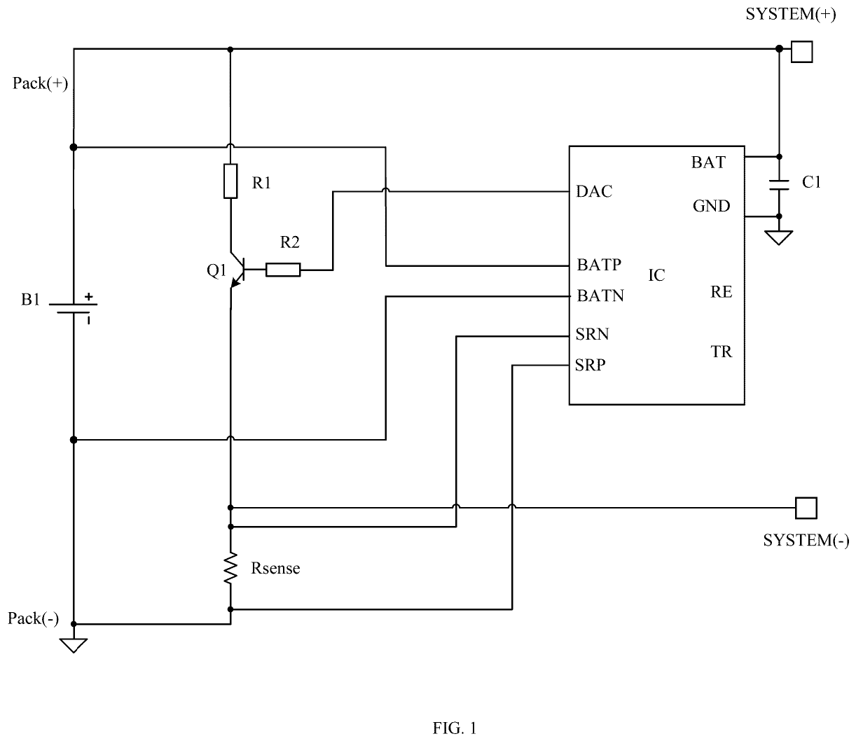

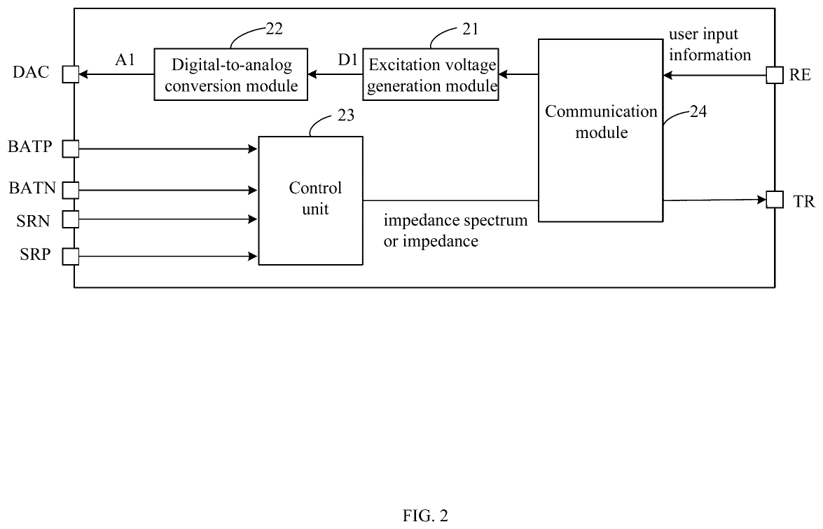

Referring now to FIG. 1, shown is a schematic circuit diagram of a first example battery impedance testing system, in accordance with embodiments of the present invention. Referring also to FIG. 2, shown is a schematic circuit diagram of a first example chip, in accordance with embodiments of the present invention. The battery impedance testing system of particular embodiments will be described in detail with reference to FIGS. 1 and 2.

A battery impedance testing system can be used for testing the impedance of battery module B1, and can include chip IC and an external circuit. Chip IC can include current excitation port DAC, voltage sampling ports BATP and BATN, and a control module. Current excitation port DAC can control an excitation current applied to battery module B1, voltage sampling ports BATP and BATN can differentially sample the response voltage generated on battery module B1, and the control module can perform Fourier transform on the excitation current and the response voltage to generate an impedance spectrum of the battery module or an impedance of the battery module at a specific frequency. For example, the excitation current can be a superposition signal of at least two square wave current signals with different frequencies.

The control module may receive user input information including at least two different frequencies, and may generate the superposition signal of at least two square wave current signals with different frequencies according to the user input information including at least two different frequencies; that is, may generate the excitation current. In particular embodiments, the control module can receive user input information including at least two different frequencies to generate at least two square wave current signals with different frequencies, and superimpose the at least two square wave current signals with different frequencies to generate the excitation current, where the frequencies of the at least two square wave current signals correspond to the at least two different frequencies in the user input information one by one.

The generation of each square wave current signal may need frequency information and amplitude information. In one embodiment, the user input information may only include frequency information. In particular embodiments, the user input information can include N different frequencies, where N is an integer greater than 1. For example, the user input information can include two different frequencies (e.g., frequency 1 and frequency 2). In this case, the amplitude information can be set to a fixed value (e.g., amplitude 1), such that the user may not need to input the amplitude information. In another example, the user input information can include frequency information and amplitude information. In particular embodiments, the user input information can include at least two combinations of frequency and amplitude. For example, the user input information can include two combinations of frequency and amplitude (e.g., the first combination: frequency 1, amplitude 1; the second combination: frequency 2, amplitude 2), where the frequencies in each combination are different, and the amplitudes in each combination can be the same or different.

The operating states of a power switch coupled in parallel with battery module B1 or the operating states of a power switch in a series structure coupled in parallel with battery module B1 can be controlled according to the excitation current generated by the user input information, in order to control the current flowing through battery module B1 to be equal to the excitation current.

In particular embodiments, the control module can receive the user input information to generate analog excitation voltage signal A1 representing the excitation current and output analog excitation voltage signal A1 at current excitation port DAC. In particular embodiments, the control module can include excitation voltage generation module 21 and digital-to-analog conversion module 22. Excitation voltage generation module 21 can receive the user input information to generate digital excitation voltage signal D1, and digital excitation voltage signal D1 may be proportional to the excitation current. In one embodiment, excitation voltage generation module 21 may generate the at least two square wave current signals with different frequencies according to the user input information to generate the excitation current, and may generate digital excitation voltage signal D1 according to the excitation current. In another embodiment, excitation voltage generation module 21 may generate digital excitation voltage signal D1 directly according to the user input information without generating the excitation current. Digital-to-analog conversion module 22 may receive digital excitation voltage signal D1 to generate analog excitation voltage signal A1.

Battery module B1 can be coupled in parallel with power switch Q1, and the control terminal of power switch Q1 may be coupled with current excitation port DAC to receive analog excitation voltage signal A1. The operating states of power switch Q1 can be controlled according to analog excitation voltage signal A1, such that the current flowing through battery module B1 is controlled to be equal to the excitation current. In particular embodiments, power switch Q1 may operate in a linear state, and the resistance value of power switch Q1 can be controlled according to analog excitation voltage signal A1 to control the current flowing through the battery module to be equal to the excitation current. The resistance of power switch Q1 may be inversely proportional to analog excitation voltage signal A1, and the current flowing through power switch Q1 can be directly proportional to analog excitation voltage signal A1.

In particular embodiments, power switch Q1 can be a bipolar-junction transistor (BJT), but any suitable transistor (e.g., MOS transistor) or switching device can be employed in certain embodiments. In particular embodiments, battery module B1 can be coupled in parallel with the series structure including power switch Q1 and current limiting resistor R1, but other arrangements can also be supported in certain embodiments. For example, the battery impedance testing system may not include current limiting resistor R1, and power switch Q1 can be coupled in parallel with battery module B1. Also, the positions of power switch Q1 and current limiting resistor R1 can be different in certain embodiments. In particular embodiments, the control terminal of power switch Q1 can connect to current excitation port DAC through resistor R2, but other arrangements are supported in certain embodiments. For example, the control terminal of power switch Q1 may be directly connected to current excitation port DAC.

The control module also can include control unit 23 that can receive the response voltage or receive the response voltage and the excitation current, perform Fourier transform on the excitation current and the response voltage to obtain an amplitude spectrum and a phase spectrum of the impedance, and generate an impedance spectrum of the battery module or an impedance of the battery module at a specific frequency according to the amplitude spectrum and the phase spectrum of the impedance. In particular embodiments, control unit 23 may perform Fourier transform on the excitation current and the response voltage to generate a current Fourier transform formula and a voltage Fourier transform formula, may generate the amplitude spectrum of the impedance according to the ratio of the amplitude in the voltage Fourier transform formula and the amplitude in the current Fourier transform formula, may generate the phase spectrum of the impedance according to the difference between the phase in the voltage Fourier transform formula and the phase in the current Fourier transform formula, and/or may generate the impedance spectrum of battery module B1 or the impedance of the battery module at a specific frequency according to the amplitude spectrum and the phase spectrum of the impedance.

In particular embodiments, the chip also can include receiving port RE and transmitting port TR. The user can input the user input information including frequency information or frequency and amplitude information through receiving port RE, and control unit 23 may generate the impedance spectrum of battery module B1 or the impedance of battery module B1 at a specific frequency and outputs the impedance spectrum or the impedance at transmitting port TR. Moreover, the control module also can include communication module 24, both receiving port RE and transmitting port TR communicate with other modules in the chip through communication module 24. In particular embodiments, receiving port RE can transmit the user input information to excitation voltage generation module 21 through communication module 24, and control unit 23 may output the impedance spectrum of battery module B1 or the impedance of battery module B1 at a specific frequency from transmitting port TR through communication module 24.

In particular embodiments, the chip can include receiving port RE and transmitting port TR, such that communication module 24 correspondingly can include a receiver and a transmitter, but the invention is not limited to this. In other embodiments, the chip can include a receiving/transmitting port, and communication module 24 correspondingly can include a transceiver. In particular embodiments, battery module B1 may be a single battery, or a battery pack including a plurality of batteries coupled in parallel or/and in series. In particular embodiments, the SYSTEM(+) and SYSTEM(−) ports in FIG. 1 can couple electrical equipment.

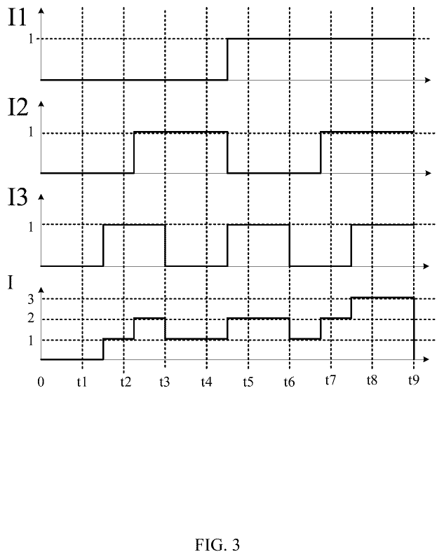

Referring now to FIG. 3, shown is a waveform diagram of an example excitation current, in accordance with embodiments of the present invention. In this particular example, I1 is a square wave current signal generated according to the first frequency (or the first combination of the frequency and amplitude) in the user input information given by the user, I2 is a square wave current signal generated according to the second frequency (or the second combination of the frequency and amplitude) in the user input information given by the user, I3 is a square wave current signal generated according to the third frequency (or the third combination of the frequency and amplitude) in the user input information given by the user, I is the excitation current, and the first to third frequencies are different. In particular embodiments, excitation current I may be obtained by superposing three square wave current signals I1 to I3 with different frequencies. However, the scheme that N (N is greater than 2) square wave current signals with different frequencies are superimposed to obtain the excitation current can also be supported in certain embodiments.

In particular embodiments, the three frequencies in the user input information are 1/900 (HZ), 1/450 (HZ) and 1/300 (HZ) respectively, and the frequencies of square wave current signals I1-I3 are 1/900 (HZ), 1/450 (HZ) and 1/300 (HZ) respectively, such that the periods of square wave current signals I1-I3 are 900 s, 450 s and 300 s. In addition, the amplitudes of square wave current signals I1-I3 are 1. Excitation current I shown in FIG. 3 can be obtained by superimposing square wave current signals I1 to I3, that is, I=I1+I2+I3, which is a quaternary sequence, e.g., excitation current I can include four types current amplitude, e.g., 0, 1, 2, 3. It should be understood that the three frequencies 1/900, 1/450 and 1/300 in the user input information here are one particular example, and the user input information can include two or more different frequencies can also be supported in certain embodiments.

The resistance value of power switch Q1 can be controlled according to excitation current I shown in FIG. 3, such that the current flowing through battery module B1 is equal to excitation current I. The control module also can include an analog-to-digital conversion module (not shown in FIG. 2) that can convert the response voltage differentially sampled by voltage sampling ports BATP and BATN into a digital response voltage.

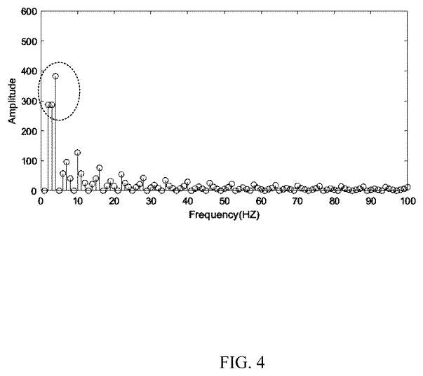

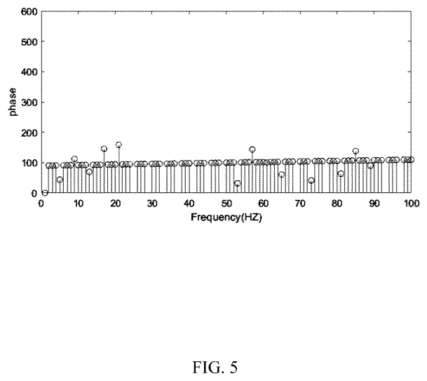

Referring now to FIG. 4, shown is a schematic diagram of an example amplitude spectrum of the impedance, in accordance with embodiments of the present invention. Referring also to FIG. 5, shown is a schematic diagram of an example phase spectrum of the impedance, in accordance with embodiments of the present invention. The control module can perform Fourier transform on the excitation current generated by the chip and the digital response voltage to generate a current Fourier transform formula and a voltage Fourier transform formula, generate an amplitude spectrum (see, e.g., FIG. 4) of the impedance according to the ratio of the amplitude in the voltage Fourier transform formula to the amplitude in the current Fourier transform formula, generate a phase spectrum (see, e.g., FIG. 5) of the impedance according to the difference between the phase in the voltage Fourier transform formula and the phase in the current Fourier transform formula, and/or generate the impedance spectrum of the battery module or the impedance of the battery module at a specific frequency according to the amplitude spectrum and the phase spectrum of the impedance.

As shown in FIG. 4, due to the existence of noise interference, points with the amplitude lower than 200 in the amplitude spectrum of the impedance may be discarded, such that the effective frequency points in FIG. 4 are three points in the dashed box, the amplitudes corresponding to the three effective frequency points can be obtained from FIG. 4, and the phases corresponding to the three effective frequency points can be obtained from FIG. 5. Further, according to the amplitudes and phases corresponding to the three effective frequency points, three points in the impedance spectrum can be obtained. By repeating the above process, the amplitudes and phases of multiple points in the impedance spectrum can be obtained, thus obtaining the impedance spectrum of the battery module. It should be noted that the number of effective frequency points obtained from each testing may be the same as the number of square wave current signals with different frequencies in the excitation current. That is, the number of effective frequency points obtained from each testing can be the same as the number of different frequencies in the user input information. It should be noted that discarding points with the amplitude lower than 200 is only one particular example, and other threshold values can be supported in certain embodiments. For example, the threshold value of discarding can be related to the amplitude of the noise interference.

In particular embodiments, the chip may utilize voltage sampling ports BATP and BATN to differentially sample the voltage across battery module B1. In other examples, the voltage across battery module B1 can be generated by sampling the voltage at voltage sampling port BATP, e.g., at a single terminal, such that the chip may only have one voltage sampling port BATP. In particular embodiments, the chip also can include current sampling ports SRN and SRP, which can be used to differentially sample the actual excitation current of battery module B1 for Fourier transform. In particular embodiments, the battery impedance testing system also can include current sampling resistor Rsense, which may be coupled in series with power switch Q1, and current sampling ports SRN and SRP can be used for differentially sampling the voltages at both ends of current sampling resistor Rsense for characterizing the actual excitation current. In one embodiment, the chip may only include current sampling port SRN, and the voltage of current sampling resistor Rsense can be sampled at a single terminal. In another example, the actual excitation current may not be sampled, and excitation current I as shown in FIG. 3 generated by the chip according to the user input information may be directly used for Fourier transform.

In FIGS. 3-5, the user input information can include three different frequencies to generate three square wave current signals with different frequencies, and then the three square wave current signals with different frequencies are superimposed to generate the excitation current as an example, but any scheme that the excitation current is configured as the superposition signal of at least two square wave current signals with different frequencies can be supported in certain embodiments.

As shown in FIG. 4, the battery impedance testing method of particular embodiments can obtain the impedance of multiple effective frequency points through one testing, thereby reducing the testing times and accelerating the testing speed, and the number of effective frequency points obtained from each testing is the same as the number of different frequencies in the user input information. However, the above-mentioned battery impedance testing system utilizes digital-to-analog conversion module 22, which may have a relatively high cost and occupy a relatively large area of the chip. In order to reduce the cost and facilitate miniaturization of the chip, the second example of battery impedance testing system without digital-to-analog conversion module 22 is described below.

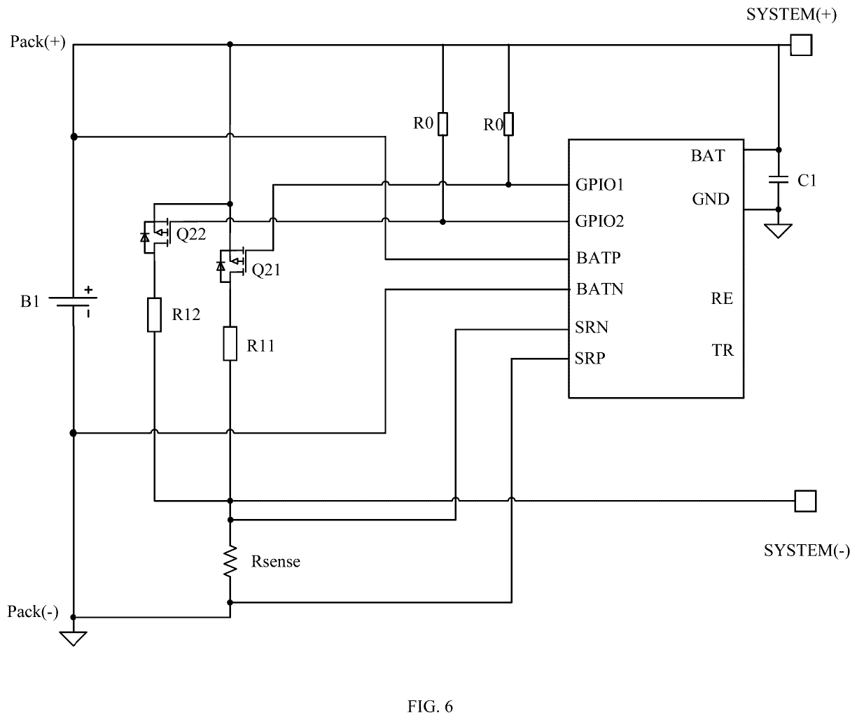

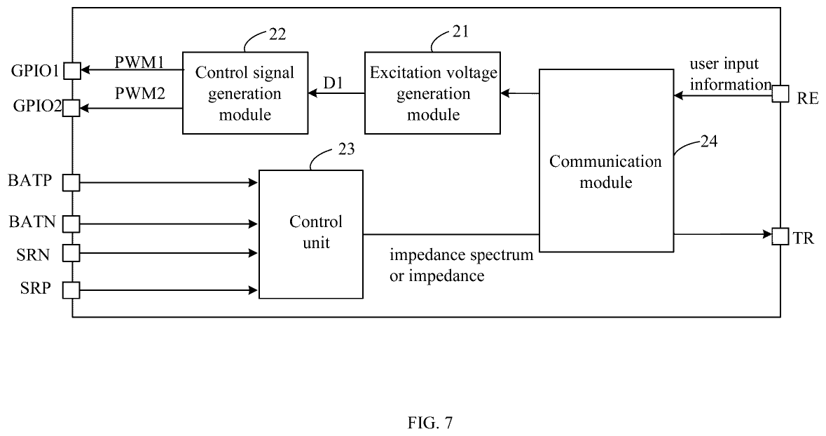

Referring now to FIG. 6, shown is a schematic circuit diagram of a second example battery impedance testing system, in accordance with embodiments of the present invention. Referring also to FIG. 7, shown is a schematic circuit diagram of a second example chip, in accordance with embodiments of the present invention. In this particular example, digital-to-analog conversion module 22 of FIG. 2 may not be included, and the current flowing through battery module B1 can be controlled to be equal to the excitation current by increasing the number of the current excitation ports to increase the types of current amplitude of the current flowing through battery module B1. The chip can include at least two current excitation ports, but other arrangements can be supported in certain embodiments. For example, the number of specific current excitation ports can be flexibly selected according to user requirements.

In particular embodiments, the battery impedance testing system can include a plurality of series structures, and each series structure can be coupled in parallel with battery module B1. Each series structure can include resistor R1i and power switch Q2i coupled in series, and each current excitation port (e.g., GPIO1 and GPIO2 in FIG. 6) may correspond to one series structure, respectively. Each current excitation port can be coupled to the control terminal of power switch Q2i in the corresponding series structure, where the resistance of resistor R1i in each series structure is different.

The control module can include excitation voltage generation module 21 and control signal generation module 22, where excitation voltage generation module 21 may generate digital excitation voltage signal D1 according to the user input information, and digital excitation voltage signal D1 can be proportional to the excitation current. Also, control signal generation module 22 can generate the control signals of the second power switches in series structures respectively according to digital excitation voltage signal D1.

According to the switching states of power switch Q2i in each series structure, whether each first resistor is coupled in parallel with battery module B1 can be controlled to control the resistance value of a resistor coupled in parallel with the battery module, in order to control the current flowing through the battery module to be equal to the excitation current. For example, the current flowing through the battery module can be configured as the ratio of the voltage of the battery module to the resistance value of the resistor coupled in parallel with the battery module. Also, power switch Q2i may operate in an on or off state.

In particular embodiments, the chip can include current excitation ports GPIO1 and GPIO2 corresponding to two series structures, namely, a first series structure and a second series structure respectively corresponding to current excitation ports GPIO1 and GPIO2. Resistor R11 and power switch Q21 can connect in series to form the first series structure, and resistor R12 and power switch Q22 can connect in series to form the second series structure. When power switches Q21 and Q22 are both turned off, the current flowing through battery module B1 may be 0. When power switch Q21 is turned on and power switch Q22 is turned off, the current flowing through battery module B1 can be Vbat/R11, where Vbat is the voltage of battery module B1. When power switch Q21 is turned on and power switch Q22 is turned on, the excitation current flowing through battery module B1 can be Vbat/R, where R is the resistance value of resistors R11 and R12 connected in parallel. When power switch Q21 is turned off and power switch Q22 is turned on, the excitation current flowing through battery module B1 can be Vbat/R12, such that four types current amplitude 0, Vbat/R11, Vbat/R, and Vbat/R12 are obtained according to the turn-on and turn-off states of each power switch Q2i. Therefore, control signals PWM1 and PWM2 can be generated according to the excitation current generated by the user input information to control the switching states of power switches Q21 and Q22, respectively. Thus, the current flowing through current module B1 can be controlled to be equal to the excitation current, such as the excitation current shown in FIG. 3.

Particular embodiments may also provide a battery impedance testing method, which can include: applying an excitation current to a battery module; sampling the response voltage generated on the battery module; performing Fourier transform on the excitation current and the response voltage to generate an impedance spectrum of the battery module or an impedance of the battery module at a specific frequency; and where the excitation current is configured as a superposition signal of at least two square wave current signals with different frequencies.

The battery impedance testing method also can include: receiving user input information comprising at least two different frequencies to generate the at least two square wave current signals with different frequencies, and superposing the at least two square wave current signals with different frequencies to generate the excitation current, where frequencies of the at least two square wave current signals respectively correspond to the at least two different frequencies in the user input information. Operating states of a power switch coupled in parallel with the battery module or a power switch in a series structure coupled in parallel with the battery module is controlled according to the excitation current, in order to control a current flowing through the battery module to be equal to the excitation current.

In one embodiment, the battery impedance testing method also can include: receiving user input information comprising at least two different frequencies and generating the at least two square wave current signals with different frequencies to generate a digital excitation voltage signal representing the excitation current, where the digital excitation voltage signal is directly proportional to the excitation current; and generating an analog excitation voltage signal according to the digital excitation voltage signal.

The battery module is coupled in parallel with a first power switch or a series structure formed by coupling the first power switch and a current limiting resistor in series, and a control terminal of the first power switch may receive the analog excitation voltage signal. The first power switch may operate in a linear state, and a resistance value of the first power switch is can be controlled according to the analog excitation voltage signal to control a current flowing through the battery module to be equal to the excitation current.

In another embodiment, the chip can include at least two current excitation ports, each of which corresponds to a series structure formed by coupling a first resistor and a second power switch in series. Each of at least two series structure may be coupled in parallel with the battery module, and each series structure can be formed by coupling a first resistor and a second power switch in series, where a resistance of the first resistor in each series structure is different.

The battery impedance testing method also can include: receiving user input information comprising at least two different frequencies and generating the at least two square wave current signals with different frequencies to generate a digital excitation voltage signal representing the excitation current, where the digital excitation voltage signal is directly proportional to the excitation current; and generating control signals of the second power switches in series structures respectively according to the digital excitation voltage signal to respectively control switching states of second power switches.

The second power switch operates in an on or off state. Controlling whether each first resistor is coupled in parallel with the battery module according to switching states of the second power switch in each series structure to control a resistance value of a resistor coupled in parallel with the battery module, such that a current flowing through the battery module is controlled to be equal to the excitation current, where the current flowing through the battery module is configured as a ratio of a voltage of the battery module to the resistance value of the resistor coupled in parallel with the battery module.

The battery impedance testing method also can include: performing Fourier transform on the excitation current and the response voltage to obtain an amplitude spectrum and a phase spectrum of an impedance of the battery module; and generating the impedance spectrum of the battery module or the impedance of the battery module at a specific frequency according to the amplitude spectrum and the phase spectrum of the impedance.

The battery impedance testing method also can include: performing Fourier transform on the excitation current and the response voltage to generate a current Fourier transform formula and a voltage Fourier transform formula; generating the amplitude spectrum of the impedance according to a ratio of an amplitude in the voltage Fourier transform formula and an amplitude in the current Fourier transform formula; and generating the phase spectrum of the impedance according to a difference between a phase in the voltage Fourier transform formula and a phase in the current Fourier transform formula.

The embodiments were chosen and described in order to best explain the principles of the invention and its practical applications, to thereby enable others skilled in the art to best utilize the invention and various embodiments with modifications as are suited to particular use(s) contemplated. It is intended that the scope of the invention be defined by the claims appended hereto and their equivalents.

What is claimed is:

1. A chip for testing an impedance of a battery module, the chip comprising:
a) at least one current excitation port configured to control an excitation current applied to the battery module;
b) at least one voltage sampling port configured to sample a response voltage generated on the battery module;
c) a control module configured to perform Fourier transform on the excitation current and the response voltage to generate impedance information of the battery module; and
d) wherein the excitation current is configured as a superposition signal of at least two square wave current signals with different frequencies.

2. The chip of claim 1, wherein the control module is configured to receive user input information comprising at least two different frequencies to generate the at least two square wave current signals with different frequencies, and to superimpose the at least two square wave current signals with different frequencies to generate the excitation current, wherein frequencies of the at least two square wave current signals respectively correspond to the at least two different frequencies in the user input information.

3. The chip of claim 1, wherein operating states of a power switch coupled in parallel with the battery module or a power switch in a series structure coupled in parallel with the battery module is controlled according to the excitation current, in order to control a current flowing through the battery module to be equal to the excitation current.

4. The chip of claim 1, further comprising:
a) an excitation voltage generation module configured to receive user input information comprising at least two different frequencies and generate the at least two square wave current signals with different frequencies to generate a digital excitation voltage signal representing the excitation current, wherein the digital excitation voltage signal is directly proportional to the excitation current; and
b) a digital-to-analog conversion module configured to receive the digital excitation voltage signal to generate an analog excitation voltage signal and output the analog excitation voltage signal at the current excitation port.

5. The chip of claim 4, wherein the battery module is coupled in parallel with a first power switch or a series structure comprising a first power switch and a current limiting resistor coupled in series, and a control terminal of the first power switch is coupled with the current excitation port to receive the analog excitation voltage signal.

6. The chip of claim 5, wherein the first power switch operates in a linear state, and a resistance value of the first power switch is controlled according to the analog excitation voltage signal to control a current flowing through the battery module to be equal to the excitation current.

7. The chip of claim 1, wherein:
a) the chip can include at least two current excitation ports, each of which corresponds to a series structure comprising a first resistor and a second power switch coupled in series;
b) each series structure is coupled to the battery module in parallel, and each current excitation port is coupled to a control terminal of the second power switch in a corresponding series structure; and
c) a resistance of the first resistor in each series structure is different.

8. The chip of claim 7, further comprising:
a) an excitation voltage generation module configured to receive user input information comprising at least two different frequencies and generate the at least two square wave current signals with different frequencies to generate a digital excitation voltage signal representing the excitation current, wherein the digital excitation voltage signal is directly proportional to the excitation current; and
b) a control signal generation module configured to generate control signals of the second power switches in the series structures respectively according to the digital excitation voltage signal.

9. The chip of claim 7, wherein the second power switch operates in an on state or an off state.

10. The chip of claim 7, wherein:
a) controlling whether each first resistor is coupled in parallel with the battery module according to switching states of the second power switch in each series structure to control a resistance value of a resistor coupled in parallel with the battery module, such that a current flowing through the battery module is controlled to be equal to the excitation current; and
b) the current flowing through the battery module is configured as a ratio of a voltage of the battery module to the resistance value of the resistor coupled in parallel with the battery module.

11. The chip of claim 1, wherein the control module is configured to perform Fourier transform on the excitation current and the response voltage to generate an amplitude spectrum and a phase spectrum of an impedance of the battery module, and generate the impedance information of the battery module according to the amplitude spectrum and the phase spectrum of the impedance.

12. The chip of claim 1, further comprising at least one current sampling port configured to sample the actual excitation current flowing through the battery module for Fourier transform.

13. A method of battery impedance testing, the method comprising:
a) applying an excitation current to a battery module;
b) sampling a response voltage generated on the battery module;
c) performing Fourier transform on the excitation current and the response voltage to generate impedance information of the battery module; and
d) wherein the excitation current is configured as a superposition signal of at least two square wave current signals with different frequencies.

14. The method of claim 13, further comprising:
a) receiving user input information comprising at least two different frequencies to generate the at least two square wave current signals with different frequencies;
b) superposing the at least two square wave current signals with different frequencies to generate the excitation current; and
c) wherein frequencies of the at least two square wave current signals respectively correspond to the at least two different frequencies in the user input information.

15. The method of claim 13, wherein operating states of a power switch coupled in parallel with the battery module or a power switch in a series structure coupled in parallel with the battery module is controlled according to the excitation current, in order to control a current flowing through the battery module to be equal to the excitation current.

16. The method of claim 13, further comprising:
a) receiving user input information comprising at least two different frequencies and generating the at least two square wave current signals with different frequencies to generate a digital excitation voltage signal representing the excitation current, wherein the digital excitation voltage signal is directly proportional to the excitation current; and
b) generating an analog excitation voltage signal according to the digital excitation voltage signal.

17. The method of claim 16, wherein:
a) the battery module is coupled in parallel with a first power switch or a series structure comprising the first power switch and a current limiting resistor coupled in series, and a control terminal of the first power switch receives the analog excitation voltage signal; and
b) the first power switch operates in a linear state, and a resistance value of the first power switch is controlled according to the analog excitation voltage signal to control a current flowing through the battery module to be equal to the excitation current.

18. The method of claim 13, wherein each of at least two series structure is coupled in parallel with the battery module, and each series structure comprising a first resistor and a second power switch coupled in series, wherein a resistance of the first resistor in each series structure is different.

19. The method of claim 18, further comprising:
a) receiving user input information comprising at least two different frequencies and generating the at least two square wave current signals with different frequencies to generate a digital excitation voltage signal representing the excitation current, wherein the digital excitation voltage signal is directly proportional to the excitation current; and
b) generating control signals of the second power switches in series structures respectively according to the digital excitation voltage signal to respectively control switching states of second power switches.

20. The method of claim 18, wherein:
a) the second power switch operates in an on state or an off state;
b) controlling whether each first resistor is coupled in parallel with the battery module according to switching states of the second power switch in each series structure to control a resistance value of a resistor coupled in parallel with the battery module, such that a current flowing through the battery module is controlled to be equal to the excitation current; and
c) the current flowing through the battery module is configured as a ratio of a voltage of the battery module to the resistance value of the resistor coupled in parallel with the battery module.
